(19) United States
(12) Patent Application Publication
(10) Pub. No.: US 2001/0016388 A1
(43) Pub. Date: Aug. 23, 2001

(54) Method for fabricating semiconductor device

(76) Inventors: Shin Koyama, Tokyo (JP); Koichi Ando, Tokyo (JP); Shunichiro Kuroki, Tokyo (JP)

Correspondence Address: HELFGOTT & KARAS, P.C., EMPIRE STATE BUILDING, 60TH FLOOR, NEW YORK, NY, 10118, US

(21) Appl. No.: 09/785,587

(22) Filed: Feb. 16, 2001

(30) Foreign Application Priority Data
Feb. 22, 2000 (JP) 44038/2000

(51) Int. Cl. H01L 21/8234

(52) U.S. Cl. 438/275

(57) ABSTRACT

The semiconductor device fabrication method of the present invention comprises an impurity introduction step of introducing an impurity capable of accelerating thermal oxidation selectively into a first region of the surface of a silicon substrate and an oxidation step of successively carrying out oxidation and oxynitridation for said first region and a second region where no impurity is introduced and forming insulating films with respectively different film thicknesses on the surface of said first region and the surface of said second region.

### BACKGROUND OF THE INVENTION

1. Field of the Invention

The present invention relates to a method for fabricating a semiconductor device, particularly, to a method for forming a semiconductor device having a variety of types of gate insulating films in a semiconductor chip.

2. Description of the Prior Art

A semiconductor device has still tended to a higher density, a higher integration, a higher speed, and a more multifunctional capability. And, a gate insulating film of an insulated gate field-effect transistor (MOS transistor) can be effectively made as thin as about 2 nm in the case of a gate length of 0.1 μm.

In general, in a semiconductor device, the power consumption and the operating voltage has been tried to be lowered. For example, if the design size becomes around 0.1 μm, a semiconductor device is operated by power source voltage at about 1.5 V. In such a state, a plurality of types of gate insulating films (hereafter referred to as multigate insulating films) has been used for a MOS transistor constituting a semiconductor device. For example, the film thickness of a silicon oxide film composing the gate insulating film is made thin in a MOS transistor constituting an inner circuit of a semiconductor device, whereas the film thickness of a silicon oxide film, a gate insulating film, is made thick in a MOS transistor constituting an outer circuit or an interface circuit of a semiconductor device.

In the future, a semiconductor device will further be constituted to be multifunctional and a nonvolatile memory such as a logic circuit, a memory circuit, an analog circuit, and an EEPROM type flash memory as well are mounted together on a semiconductor chip. It is therefore required to form a variety of types of gate insulating films in a semiconductor device. Incidentally, the film thickness of the respective multigate insulating films is 3 nm or less by conversion into a silicon oxide film and the effective difference of the film thickness of these films is 0.5 nm or less. It is hence essential to control the film thickness difference to such an extent. For such a gate insulating film, a film needed is an ultrathin silicon oxide film or an oxynitride film formed by thermal nitridation of a silicon oxide film.

Further, for a most advanced CMOS device, a dual gate structure to be a surface channel type is employed in order to prevent a short channel effect. The dual gate structure is a structure in which a p-type gate silicon layer is used for a p-channel type MOS transistor and an n-type gate silicon layer is used for an n-channel type MOS transistor.

In such a dual gate structure, as a gate insulating film is made further thin, boron existing in the gate silicon layer penetrates the gate insulating film and reaches the surface of a silicon substrate. It is, therefore, required to use an oxynitride film for a gate insulating film in order to prevent such breakthrough of boron.

Up to now, various methods have been proposed to form a multigate insulating film in a MOS transistor constituting a semiconductor device. Today, two type gate oxide films are formed in a semiconductor device of a logic circuit and a technique described in Japanese Patent Application Laid-Open No. 58-100450 (hereafter referred to as a first conventional example) is generally employed as the formation method, taking mass productivity into consideration.

Below, the formation method of two type gate oxide films described in the foregoing Japanese Patent Application Laid-Open No. 58-100450 and presently employed in mass production will be described according to FIG. 10 and FIG. 11. As illustrated in FIG. 10A, a field oxide film 102 is formed selectively on the surface of a silicon semiconductor substrate 101. A protective oxide film 103 is formed by thermal oxidation of the silicon semiconductor substrate 101 and a well layer 105 is formed by ion implantation with an impurity ion 104 and thermal treatment to control the threshold voltage of a MOS transistor.

As illustrated in FIG. 10B, the protective oxide film 103 is removed to expose an active region of the silicon semiconductor substrate 101. Next, as illustrated in FIG. 10C, thermal oxidation is carried out to form a first gate oxide film 106 on the active region of the silicon semiconductor substrate 101. After such steps being carried out, the foregoing first gate oxide film 106 is selectively etched with a chemical agent liquid such as a diluted hydrofluoric acid using a resist mask 107 formed by a well known photolithographic technique as an etching mask as illustrated in FIG. 10D.

Next, the photoresist mask 107 is removed and washing process is carried out using a mixed chemical agent liquid of sulfuric acid, hydrogen peroxide and pure water. A spontaneously oxidized film of about 0.8 nm thickness is formed on the exposed surface of the silicon substrate 101.

After that, thermal oxidation is again carried out. As illustrated in FIG. 11A, a second gate oxide film 108 and a third gate oxide film 109 is formed on the surface of the silicon semiconductor substrate 101 by the thermal oxidation. Incidentally, the third gate oxide film 109 is formed by additional oxidation of the foregoing first gate oxide film 106 and, therefore, made thicker than the second gate oxide film 108. In such a manner, two type gate oxide films with different thicknesses can be formed.

Hereafter, gate electrodes 110 are formed on the second gate oxide film 108 and the third gate oxide film 109 as illustrated in FIG. 11B by a well known photolithographic technique and dry etching technique. Then, as illustrated in FIG. 11C, diffusion layers 111 to be source/drain regions of a MOS transistor are formed. In the above described manner, a MOS transistor having gate oxide films of different thicknesses can be formed on the silicon semiconductor substrate 101.

Besides, techniques as methods for formation of multigate insulating films are described in, for example, Japanese Patent Application Laid-Open No. 4-122063 (hereafter referred to as a second conventional example) and Japanese Patent Application Laid-Open No. 6-302813 (hereafter referred to as a third conventional example). The main points of the second conventional example can be described as follows. In this case, the gate insulating film of a MOS transistor of an analog element portion of a semiconductor device is composed of an insulating film formed by thermal nitridation of a silicon oxide film and the gate insulating film of a digital element part is composed of a silicon oxide film. In such a manner, two type gate insulating films are formed. In this case, the film formation involves steps of coating an insulating film formed by thermal nitridation of a silicon oxide film with a resist mask, selectively etching and removing the insulating film, and then forming the foregoing silicon oxide film by thermal oxidation of the silicon substrate surface exposed by the foregoing etching and removing step.

Further, in the third conventional example, the foregoing silicon substrate surface is selectively subjected to thermal nitridation through the silicon oxide film on the silicon substrate in an ammonia gas-containing atmosphere. Next, the silicon oxide film is removed to expose the whole surface of the silicon substrate. After that, the whole surface is thermally oxidized. Successively, the oxidation of the silicon substrate surface subjected to the thermal nitridation is suppressed and a thin gate insulating film is formed on the region. In such a manner, two type gate insulating films are formed on a semiconductor chip.

However, regarding the foregoing first conventional example, the evenness of the film thickness of a second gate oxide film 108 to be a thin film is inferior. It is attributed to the fact that the exposed silicon semiconductor substrate 101 is rather roughened in the step of one time etching with the chemical agent liquid as described in FIG. 10D. That is, it is because the micro roughness of the surface of the silicon semiconductor substrate 101 is rather high.

Further, since the resist mask 107 is formed on the surface of the first gate oxide film 106 in this conventional technique, the first gate oxide film 106 is polluted with heavy metals to result in decrease of dielectric breakdown strength or reliability of the third gate oxide film 109 formed by reoxidation.

Further, the surface of the first gate oxide film 106 is etched in the step of removing the resist mask 107. The third gate oxide film 109 is formed by thermal oxidation of the silicon substrate two times. Hence, the controllability of the thickness of the finally formed third gate oxide film 109 is deteriorated. That is, the dispersion of the film thickness of the third gate oxide film is consequently increased in a semiconductor wafer, which is a silicon semiconductor substrate.

Further, in the foregoing second and third conventional examples, as in the first conventional example, micro roughness of the interface between the silicon substrate and the gate insulating films is heightened. Subsequently, the migration of electrons or holes is deteriorated to result in suppression of the capability improvement of the MOS transistor. Hence, such techniques are hardly capable of controlling the slight film thickness difference of gate insulating films, that is essential to satisfy requirements of a future multifunctional semiconductor device.

Furthermore, in the second conventional example, as in the first conventional example, the gate oxide film is polluted with heavy metals due to deposition of a resist mask resulting in decrease of reliability of the film. Also, in the third conventional example, the silicon substrate is doped with nitrogen and the doped region is formed to be a channel region of a MOS transistor, so that the migration of electric charge such as electrons or the like in the surface is further deteriorated to result in deterioration of the capability of the MOS transistor.

Consequently, by the techniques of the above described conventional examples, it is very difficult to form multigate insulating films with highly controlled film thickness difference and high reliability. Especially, it is extremely difficult to form multigate insulating films including an oxynitride film. As a result, the production yield of a future multifunctional and highly capable semiconductor device may significantly be decreased to increase fabrication cost of a semiconductor device and to make it difficult to provide such a semiconductor device as a product.

### BRIEF SUMMARY OF THE INVENTION

Objects of the Invention

The purposes of the present invention are to form multigate insulating films by a simple method and to provide a method for fabricating a semiconductor device with a heightened productivity and a lowered production cost.

Summary of the Invention

The method for fabricating a semiconductor device of the present invention comprises an impurity introduction step for introducing an impurity capable of accelerating thermal oxidation selectively into a first region of the surface of a silicon substrate and an oxidation step of successively carrying out oxidation and oxynitridation for said first region and a second region where no impurity is introduced and forming insulating films with respectively different film thicknesses on the surface of said first region and the surface of said second region.

### BRIEF DESCRIPTION OF THE DRAWINGS

The above-mentioned and other objects, features and advantages of this invention will become more apparent by reference to the following detailed description of the invention taken in conjunction with the accompanying drawings, wherein:

FIGS. 1A to 1D are cross-sectional views of a MOS transistor illustrating a first example of the present invention in fabrication process order;

FIGS. 2A and 2B are cross-sectional views of a MOS transistor illustrating a first example of the present invention in fabrication process order;

FIGS. 3A and 3B are sequence illustrations of gate insulating film formation for illustrating a first example of the present invention;

FIGS. 4A and 4B are sequence illustrations of gate insulating film formation for illustrating the effectiveness of a first example of the present invention;

FIGS. 5A to 5D are cross-sectional views of a MOS transistor illustrating a second example of the present invention in fabrication process order;

FIGS. 6A to 6C are cross-sectional views of a MOS transistor illustrating a second example of the present invention in fabrication process order;

FIGS. 7A and 7B are sequence illustrations of gate insulating film formation for illustrating a second example of the present invention;

FIG. 8 is a graph for illustrating the dependency of the acceleration effect on the dose in a gate insulating film;

FIG. 9 is a graph for illustrating the dependency of the reliability on the dose in a gate insulating film;

FIGS. 10A to 10D are cross-sectional views of a MOS transistor illustrating a conventional technique in fabrication process order; and

FIGS. 11A to 11C are cross-sectional views of a MOS transistor illustrating a conventional technique in fabrication process order.

### DETAILED DESCRIPTION OF THE INVENTION

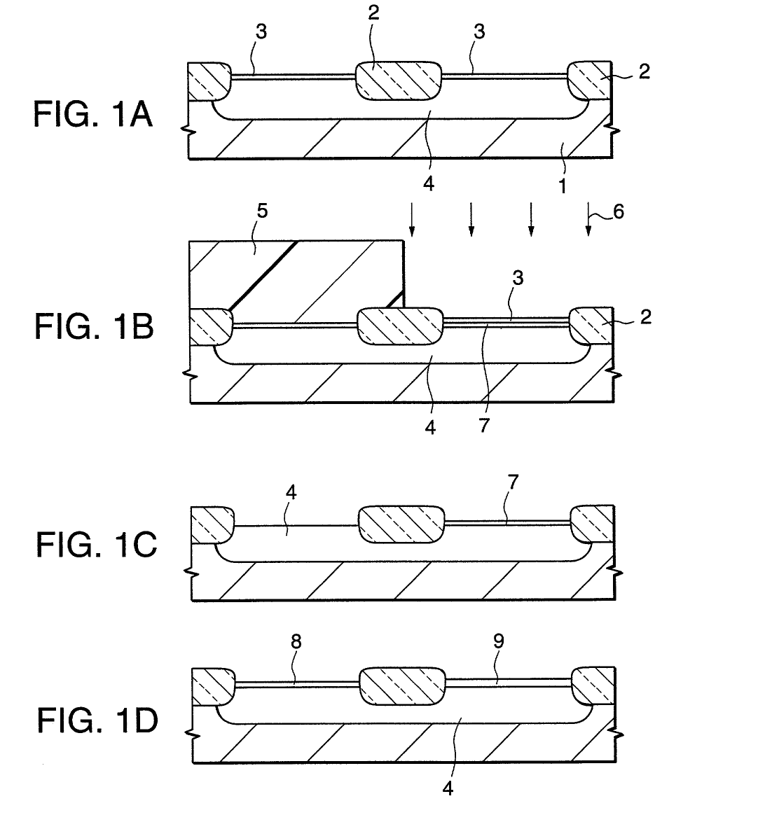

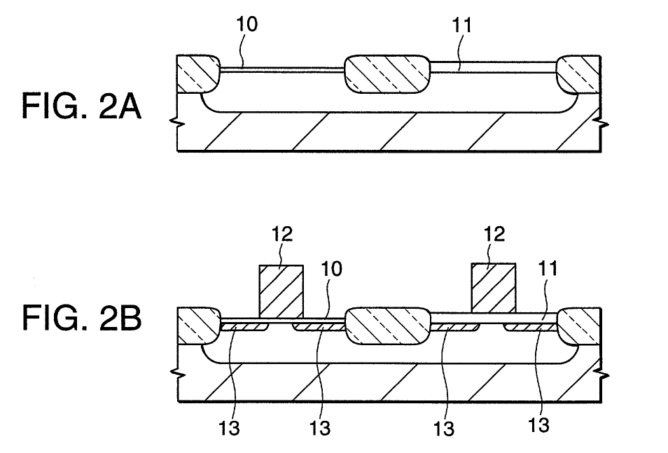

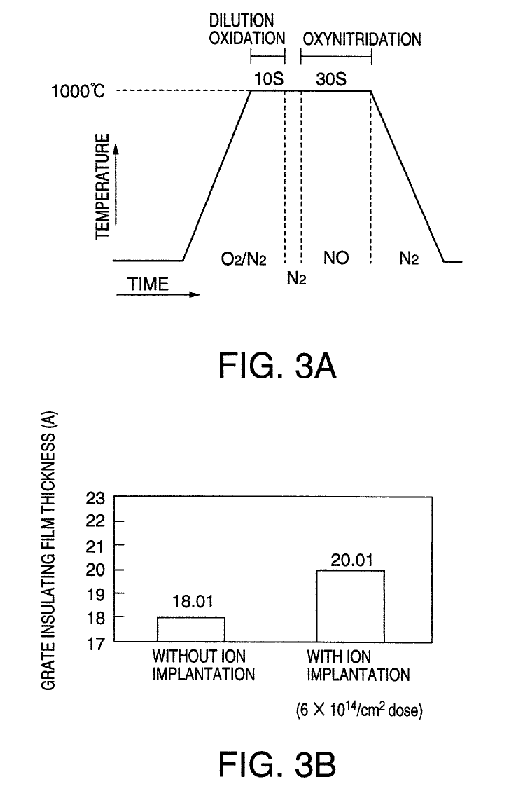

A first example of the present invention will be described below with reference to FIGS. 1, 2, and 3. FIGS. 1 and 2 are cross-sectional views of a MOS transistor illustrating the characteristics of the present invention in fabrication process order. FIG. 3 shows sequences for forming oxynitride films with different film thicknesses.

As shown in FIG. 1A, in the same manner as described for the conventional techniques, an element separating insulating film 2 is formed selectively in the surface of a silicon substrate 1. The element separating insulating film 2 is formed by a trench element separating technique or the like of filling the inside of a groove with an insulating film. Then, a protective oxide film 3 of about 5 nm film thickness is formed by thermal oxidation of the silicon substrate 1 and a well layer 4 is formed by ion implantation with an impurity ion and thermal treatment and at the same time, a threshold voltage of the resultant MOS transistor is controlled. Incidentally, the conduction type of the well layer 4 is set to be p-type or n-type corresponding to the type of the channel of the MOS transistor.

Next, as shown in FIG. 1B, a resist mask 5 is formed and an ion 6 is implanted in the surface of a prescribed region of the well layer 4 through the protective oxide film 3 using the formed mask 5 to form an ion-implanted layer 7. Fluorine ion is employed as the ion 6 and the ion implantation is carried out at around 5 kev and the dose is about 6×10¹⁴/cm². In such conditions, the region of a 10 nm or shallower surface layer of the well layer 4 can be doped with fluorine atom.

Then, as shown in FIG. 1C, the resist mask 5 is removed with a mixed solution of sulfuric acid, hydrogen peroxide, and pure water and further the protective oxide film 3 is removed to expose the surface of the well layer 4. In this case, the protective oxide film 3 is removed by etching with a diluted hydrofluoric acid solution. In such a manner, an ion-implanted layer 7 and an ion-undoped region (a region with no ion implantation) are formed in the surface of the well layer 4.

Finally, as shown in FIG. 1D, in a first step, a first oxide film 8 is formed in the surface of the foregoing ion-undoped region and a second oxide film 9 is formed in the surface of the ion-implanted layer 7. Successively, as shown in FIG. 2A, in a second step, the foregoing first and second oxide films are formed to be a first gate insulating film 10 and a second gate insulating film 11, respectively.

The sequence of the film formation described according to FIG. 1D and FIG. 2A will be described below in detail with reference to FIG. 3. FIG. 3A shows the sequence of the film formation in a RTP (a rapidly thermally processing) furnace. As shown in FIG. 3A, a silicon substrate 1 inserted into the RTP furnace is heated to 1000° C. and subjected to dilution oxidation for 10 seconds in a mixed gas atmosphere (gas pressure: about 6×10³ Pa) with 1/100 ratio of oxygen (O₂) quantity/nitrogen (N₂) quantity. This is the first step of the film formation. By the dilution oxidation, the first oxide film 8 and the second oxide film 9 described in description of FIG. 1D are formed. The film thickness of the second oxide film 9 is made thicker than that of the first oxide film 8 by the dilution oxidation. This is because accelerated oxidation occurs in the surface of the fluorine ion-implanted layer 7. Fluorine in the ion-implanted layer 7 is released from the silicon substrate surface to the outside in the foregoing dilution oxidation step and scarcely remains in the silicon substrate 1.

In succession, in the second step of the film formation, oxynitridation treatment is carried out for 30 seconds by changing the atmosphere of the inside of the RTP furnace from nitrogen to nitrogen monoxide (NO). After that, the temperature is lowered to a room temperature in the nitrogen atmosphere to take out the resultant silicon substrate. By the oxynitridation, the foregoing first and second oxide films 8 (9) are subjected to thermal nitridation to be converted into the first gate insulating film 10 and second gate insulating film 11 as described in FIG. 2A.

The film thickness difference of the first gate insulating film 10 and the second gate insulating film 11 formed in such as manner will be described with reference to FIG. 3B. As shown in FIG. 3B, in the foregoing film formation conditions, the first gate insulating film 10 of about 1.8 nm thickness by conversion into a silicon oxide film is formed in the ion-undoped region and the second gate insulating film 11 of about 2.0 nm thickness by conversion into a silicon oxide film is formed in the ion-implanted region. In this case, the film thickness difference of the gate insulating films can be controlled as highly precisely as about 0.2 nm. Like this, the present invention can control the film thickness difference of the ultrathin gate insulating films at high precision.

Next, as shown in FIG. 2B, gate electrodes 12 are formed on the first gate insulating film 10 and the second gate insulating film 11. Further, diffusion layers 13 are formed by impurity ion implantation and thermal treatment. The diffusion layers 13 are to be formed as source/drain regions of the MOS transistors and thus formed two type MOS transistors comprise gate insulating films with different film thicknesses as described above. MOS transistors with different channel types can be formed by selecting the impurities at that time. Also, a silicide layer may be formed on the surface of the gate electrodes 12 or the diffusion layers 13.

Of these two types of MOS transistors, the MOS transistor comprising the first gate insulating film composes a logic circuit of the semiconductor device and the MOS transistor comprising the second gate insulating film composes a memory circuit such as SRAM. In the case where the film thickness of a gate insulating film is as thin as about 2 nm, electric current (to be current leakage of a circuit) flows in the gate insulating film owing to direct tunnel phenomenon of the electrons during operation of a MOS transistor. Such electric current is sharply decreased with a slight increase of the thickness of the gate insulating film. Therefore, as described above, the second gate insulating film with a thick film thickness is employed for the MOS transistor composing a memory circuit which requires the current leakage to be decreased.

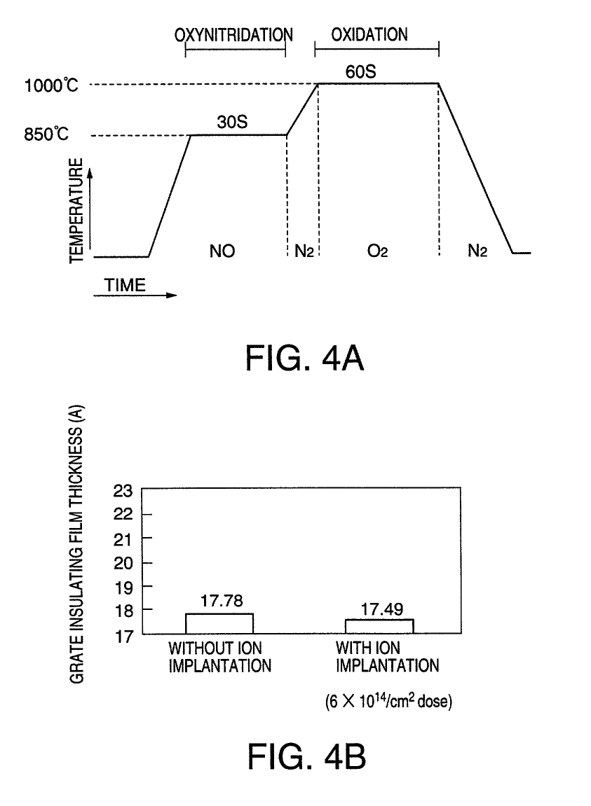

Next, the effect of the film formation sequence of the gate insulating film as illustrated in FIG. 3 of the present invention will be described in comparison with that of the sequence shown in FIG. 4. In the case illustrated in FIG. 4 as well, selective fluorine ion implantation in the silicon substrate is carried out. As in the foregoing example, the silicon substrate comprising an ion-undoped region and an ion-implanted region is subjected to film formation treatment in a RTP furnace. Incidentally, in this case, as shown in FIG. 4A, oxynitridation treatment is at first carried out in nitrogen monoxide atmosphere at 850° C. for 30 seconds. Then the temperature is increased to 1000° C. to perform oxidation treatment for 60 seconds. The gas pressure in the foregoing oxynitridation treatment is about 6×10³ Pa and the gas pressure in the foregoing oxidation treatment is about 1.2×10⁴ Pa.

However, in the conditions of the film formation in this case, an effective film thickness difference cannot be formed in the completed gate insulating films. As shown in FIG. 4B, insulating films with about 1.8 nm and about 1.7 nm thicknesses by conversion into silicon oxide films are formed respectively in the ion-undoped region and the ion-implanted region. In this case, the oxidation acceleration effect of the ion implantation on the gate insulating film does not take place at all. Even if the temperature of the oxynitridation is increased to 1000° C., the result is same.

As described, in order to draw the acceleration effect for increasing the film thickness of the gate insulating film by ion implantation, it is found, as illustrated in the example of the present invention, that oxidation such as dilution oxidation is preferable to be carried out at first and then oxynitridation is successively carried out.

Further, as the effect of the foregoing example, occurrence of micro roughness as described in the conventional techniques can significantly be suppressed. In general, after the step of FIG. 1C, a spontaneously oxidized film of about 0.8 nm film thickness and relatively significant micro roughness exist in the surface of the well layer 4. If the oxidation treatment by dilution oxidation at first and at a high temperature is carried out at that time, even in a gas atmosphere at a decreased pressure, the foregoing spontaneously oxidized film is made dense and at the same time, the thermal oxidation rate is determined by thermal diffusion of an oxidation seed such as oxygen or the like in the film during the thermal oxidation. For that, film thickness difference of the spontaneously oxidized films attributed to the micro roughness is eliminated and consequently, micro roughness is significantly suppressed. For example, the micro roughness value of about 0.2 nm is suppressed to 0.1 nm or less by the present invention.

In such a manner, the film thickness controllability of the gate insulating films is remarkably improved and the dispersion of the film thickness in a silicon wafer is significantly suppressed as well. Such effects are not relevant to the foregoing ion implantation at all. The effects of suppressing the dispersion of the film thicknesses are those derived from the foregoing sequence of the film formation.

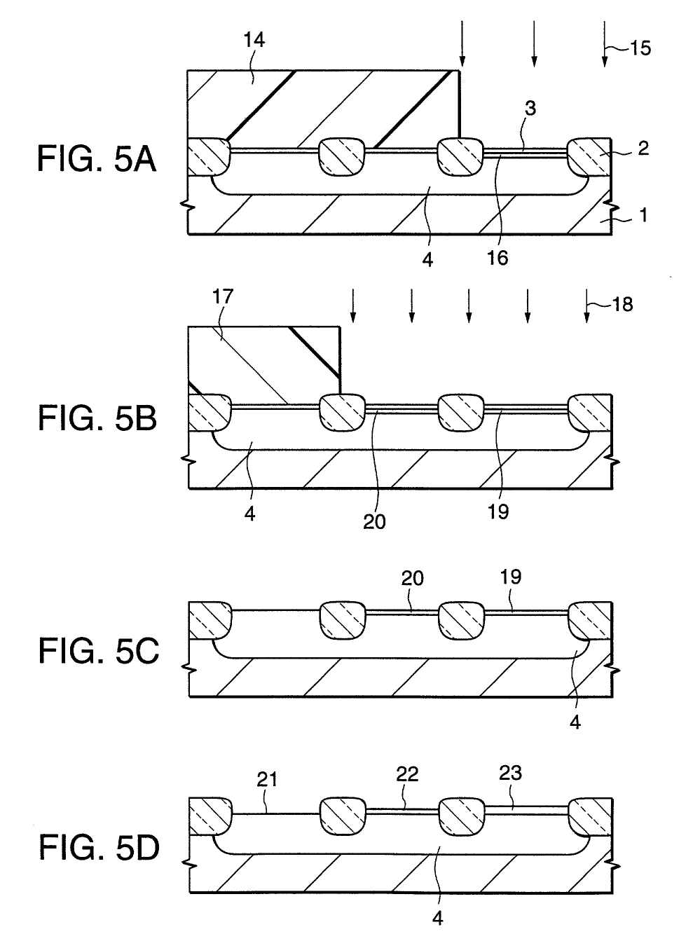

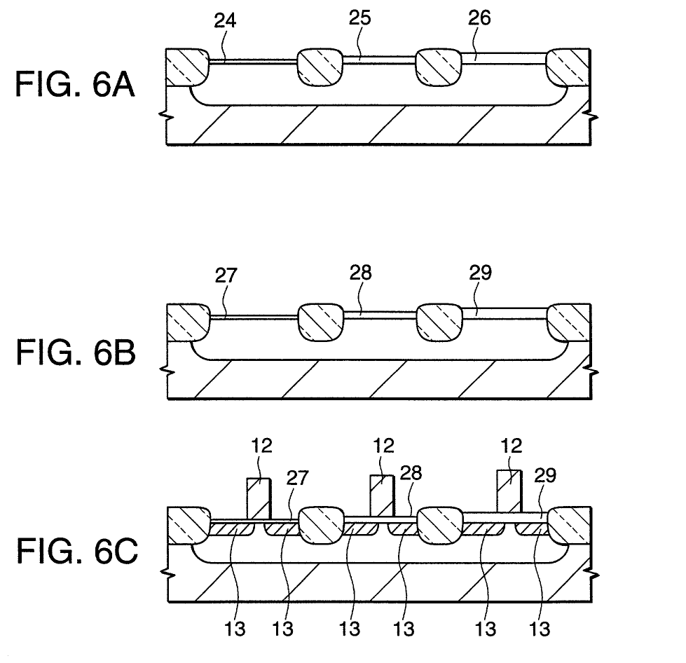

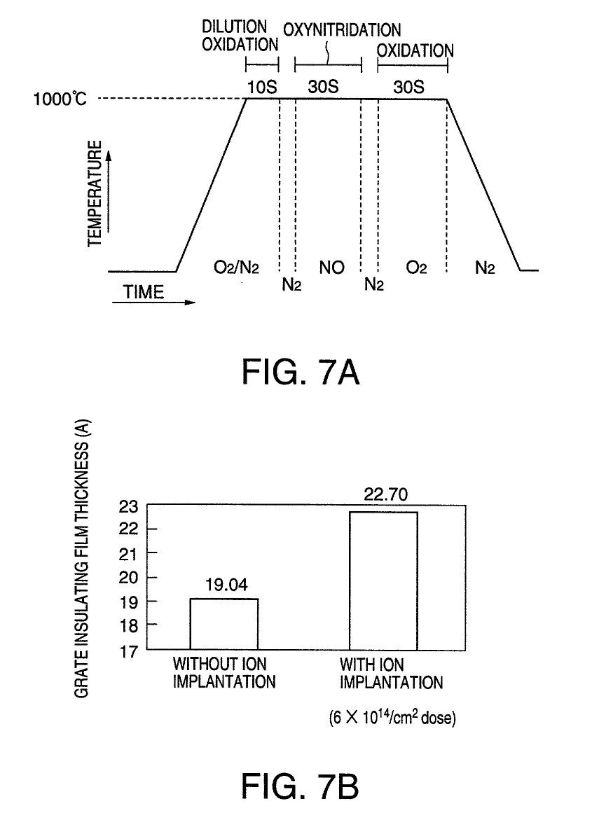

Next, a second example of the present invention will be described with reference to FIGS. 5, 6 and 7. FIGS. 5 and 6 are cross-sectional views of a MOS transistor for illustrating the characteristics of the present invention in fabrication process order. FIG. 7 shows sequences for formation of oxynitride films with different film thicknesses. In these figures, the same reference characters and numerals denote the same matters as described in the first example. The characteristics of the present example are that the sequences of the foregoing film formation are basically composed of three steps and that three or more types of gate insulating films are formed by one time film formation treatment by changing the ion implantation dose in a single semiconductor chip.

As shown in FIG. 5A, element isolating insulating films 2 are formed selectively in the surface of a silicon substrate 1 and a protective oxide film 3 is formed and a well layer 4 is formed. Then, a resist mask 14 is formed and using the resist mask, a first ion 15 is implanted in a prescribed surface of the well layer 4 to form a first ion-implanted layer 16. Also in this case, fluorine ion is used as the first ion 15. The implantation energy is about 5 keV and the dose is 1×10⁴/cm².

Next, a resist mask 17 is formed as shown in FIG. 5B and using the mask, a second ion 18 is implanted in a prescribed surface of the well layer 4. Also in this case, fluorine ion is used as the second ion 18. The implantation energy is about 5 keV and the dose is 5×10¹⁴/cm². By the additional ion implantation of the second ion 18, the first ion-implanted layer 16 becomes a first/second ion-implanted layer 19 and a second ion-implanted layer 20 is formed in a new region. Incidentally, the dose of fluorine ion in the first/second ion-implanted layer 19 becomes 6×10¹⁴/cm².

Next, as shown in FIG. 5C, the surface of the well layer 4 is exposed. In such a manner, there exist the first/second ion-implanted layer 19, the second ion-implanted layer 20, and a region where no ion is implanted in the surface of the well layer 4.

Next, as shown in FIG. 5D, in the first step, a first oxide film 21 is formed in the surface of the region where no ion is implanted, a second oxide film 22 on the surface of the second ion-implanted layer 20, and a third oxide film 23 on the surface of the first/second ion-implanted layer 19. Successively, in the second step, as shown in FIG. 6A, the foregoing first, second, and third oxide films are converted into a first oxynitride film 24, a second oxynitride film 25, and a third oxynitride film 26, respectively. Further successively, in the third step, as shown in FIG. 6B, the foregoing first, second, and third oxynitride films are converted into a first gate insulating film 27, a second gate insulating film 28, and a third gate insulating film 29, respectively.

Next, the sequence of the film formation described along the foregoing FIG. 5D and FIG. 6A will be described with reference to FIG. 7. FIG. 7A also illustrates the sequence of the film formation in a RTP furnace. As illustrated in FIG. 7A, as in the first example, dilution oxidation is at first carried out at 1000° C. for 10 seconds. By the dilution oxidation, the first oxide film 21, the second oxide film 22, and the third oxide film 23 described in FIG. 5D are formed. In the dilution oxidation process, the film thickness of the oxide films is thickened more in this order. This is because the oxidation speed is heightened more as the dose of fluorine ion is increased more. This phenomenon will be described later as an effect of the present invention.

Next, oxynitridation is carried out for 30 seconds by changing the atmospheric gas in the RTP furnace from nitrogen to nitrogen monoxide. By oxynitridation, the foregoing first, second and third oxide films 21, 22, 23 are subjected to thermal nitridation and converted into the first oxynitride film 24, the second oxynitride film 25 and third oxynitride film 26 as described in FIG. 6A. Then, further the atmospheric gas in the RTP furnace is changed from nitrogen to oxygen to carry out oxidation for 30 seconds. By the oxidation, the foregoing first oxynitride film 24, the second oxynitride film 25 and third oxynitride film 26 are converted into the first gate insulating film 27, the second gate insulating film 28 and the third gate insulating film 29 as described in FIG. 6B. Finally, the temperature is decreased to a room temperature in nitrogen atmosphere and then the resultant silicon substrate is taken out. Incidentally, the gas pressure in the foregoing dilution oxidation and oxynitridation treatment is about 6×10³ Pa and the gas pressure in the oxidation treatment is about 1.2×10⁴ Pa.

Next, the film thickness difference between the first gate insulating film 27 formed in such a manner in the region where no ion is implanted and the third gate insulating film 29 in the region implanted with the ion in the same dose as that in the first example will be described with reference to FIG. 7B. In the sequence of the film formation in three steps, the first gate insulating film 27 of about 1.9 nm thickness by conversion into a silicon oxide film is formed in the ion-undoped region and the third gate insulating film 29 of about 2.3 nm thickness by conversion into a silicon oxide film is formed in the foregoing ion-implanted region. In this case, the film thickness difference of gate insulating films can be controlled as highly precisely as about 0.4 nm. The film thickness difference is two times as large as that of the first example. In such a manner, by adding reoxidation treatment to the sequence of the film formation in the first example, the film thickness difference of the gate insulating films can be increased. Additionally, the film thickness of the second gate insulating film 28 on the foregoing second ion-implanted layer 20 with the dose of 5×10¹⁴/cm² is about 2.1 nm thickness by conversion into a silicon oxide film.

Finally, as in the first example and as shown in FIG. 6C, gate electrodes 12 are formed on the first gate insulating film 27, the second gate insulating film 28, and the third gate insulating film 29. After that, a diffusion layer 13 is formed. Like that, three types of MOS transistors are formed so as to comprise gate insulating films with different film thicknesses.

The second example provides the same effect as that of the first example. For example, the micro roughness is remarkably suppressed also in this case. The film thickness controllability of the gate insulating films is significantly heightened and the film thickness dispersion in a silicon wafer is greatly lowered. For example, the dispersion of the film thickness in a 200 mmφ wafer is ±0.016 nm (dispersion from 1.9 nm) of standard deviation σ.

Further, by the sequence of the foregoing film formation in three steps, the film thickness difference of the gate insulating films is increased more than in the case of the first example. The increase of the film thickness difference of the gate insulating films is attributed to the following mechanism described below.

That is, by the dilution oxidation in the first step, difference is once made in film thickness of oxide films on the region where no ion is implanted and on the ion-implanted region. By the next oxynitridation treatment in the second step, nitrogen is introduced into the foregoing oxide films to become insulating films with slightly changed film qualities, however no effective film thickness difference is caused. In the first example, the film thickness difference of the foregoing oxide films is caused by the ion implantation effect. Then, by the successive reoxidation treatment in the third step, oxidation of the insulating film on the region where no ion is implanted is suppressed. This is because the thinner the film thickness of the oxide films formed in the first step is, the more easily nitrogen is accumulated in the interface between the foregoing oxide films and the silicon substrate by the oxynitridation in the second step. The accumulated nitrogen suppresses oxidation by the reoxidation, so that the film thickness difference is caused between the insulating films on the region where no ion is implanted and on the ion-implanted region. The increase of the film thickness difference in the foregoing second example is attributed to such formation of film thickness difference two times.

Further, three type gate insulating films can be formed through only one time film formation treatment, so that, in the second example, the fabrication process can be shortened and the fabrication cost can be remarkably lowered as compared with those in the case where a MOS transistor comprising three or more types of gate insulating films is fabricated by the method described in the first example or by employing conventional techniques. Such effects become more apparent as the types of the gate insulating films are increased more.

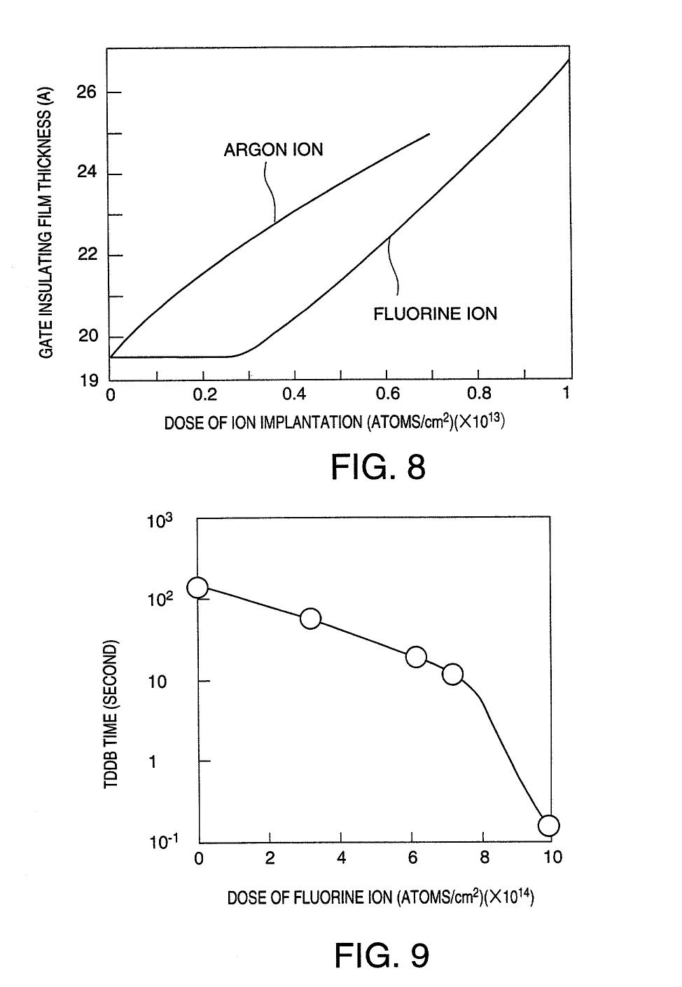

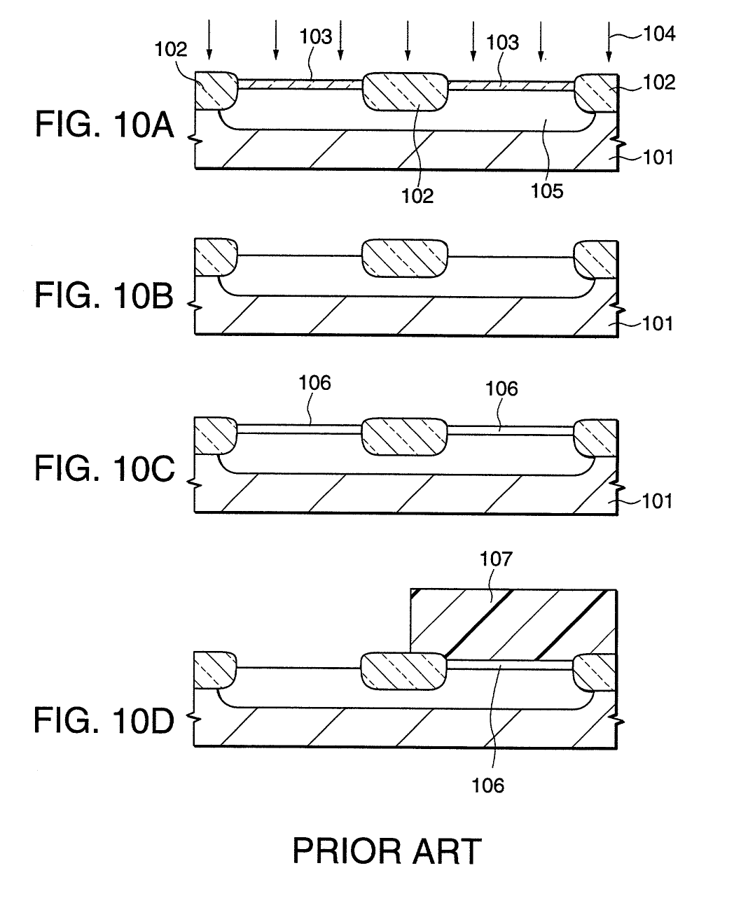

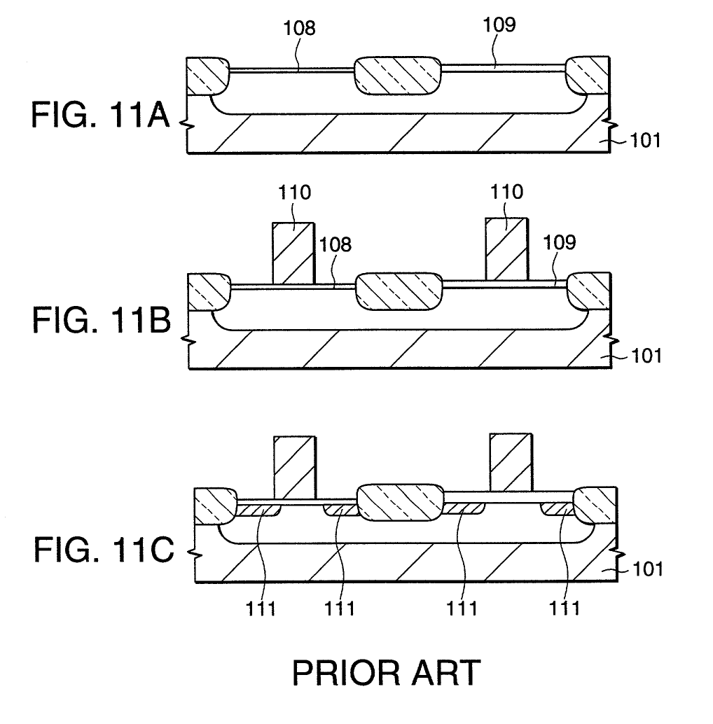

Furthermore, the description of the second example and the effects of the present invention will be described with reference to FIG. 8 or FIG. 9. FIG. 8 is a graph illustrating the correlation between the film thickness of a gate insulating film (displayed in the vertical axis) after the sequence of the foregoing film formation in three steps and implantation dose (displayed in the lateral axis) in a silicon substrate with ion (in the case of fluorine and argon). This is obtained for the first time by inventors of the present invention through testing experiments. Incidentally, the correlation illustrated in FIG. 8 does seemingly not depend on the implantation energy.

As understood from FIG. 8, in the case of ion implantation with fluorine ion, the oxidation acceleration effect for gate insulating films is not caused until the dose is 3×10¹⁴/cm² or more and thereafter, the film thickness of a gate insulating film is simply increased as the dose is increased.

In contrast with that, in the case of using argon ion for ion implantation, the acceleration effect is heightened as compared with the case of ion implantation with fluorine ion, and the acceleration effect is caused by implantation with argon and also in this case, the effect is heightened as the dose is increased.

By utilizing the above described correlation between the ion dose and the film thickness, it is made possible to form multiple types of gate insulating films in a single semiconductor chip by one time film formation treatment. Though the foregoing second example is described while exemplifying the case of ion implantation with fluorine, the method can be applied in the same manner even in the case of implantation with argon ion or implantation with a mixture of fluorine ion and argon ion. The foregoing effects are made more apparent by the conjunct implantation.

FIG. 9 is a graph illustrating the correlation between the reliability of a gate insulating film (displayed as duration until the occurrence of dielectric breakdown by TDDB in the vertical axis) after the sequence of the foregoing film formation in three steps and implantation dose (displayed in the lateral axis) in a silicon substrate with fluorine ion. This is also found for the first time by inventors of the present invention during testing experiments. The measurement conditions of TDDB (Time Dependence of Dielectric Breakdown) are as follows: the silicon substrate temperature: a room temperature, the surface area of a MOS diode: 0.1 cm², stress electric current: 0.1 A/cm².

As understood from FIG. 9, when the dose of implanted fluorine ion exceeds 7×10¹⁴/cm², the TDDB duration is sharply shortened. This is supposedly because if the fluorine ion quantity in a silicon substrate is increased, fluorine remains in a gate insulating film to deteriorate the reliability of the film. Nevertheless, the reason has not yet been made clear. In any case, in order to make effective film thickness difference by fluorine ion implantation, it is effective to set the range of the dose to be not less than 3×10¹⁴/cm² and not more than 7×10¹⁴/cm².

Also in the case of argon ion implantation, the upper limit of the dose is supposed to exist from a viewpoint of reliability of a gate insulating film. Further, in the case of ion implantation with ions besides argon ion and fluorine ion, the similar effect exists.

Though the foregoing example is described while exemplifying fluorine ion and argon ion as the ion for ion implantation, ions of halogens such as chlorine and of rare gases such as neon, xenon, and the like may similarly be employed.

Though, in the foregoing example, the ion implantation method is exemplified as a method for introducing an impurity which is capable of accelerating thermal oxidation, there exists plasma doping method as such a method for introducing an impurity. For example, impurity introduction can be carried out using an ECR (Electron Cyclotron Resonance) apparatus by exciting argon by plasma, drawing argon ion at several keV of acceleration voltage by applying acceleration voltage, and irradiating the argon ion with the foregoing kinetic energy. Incidentally, in the case of doping with fluorine as an impurity, fluorine is used instead of argon.

Furthermore, though, in the foregoing example, the description is given while exemplifying the case of employing nitrogen monoxide as an atmospheric gas for oxynitridation, the similar effect is obtained by using a nitrous oxide gas.

Further, though, in the foregoing example, thermal oxidation in the first step of the sequence of film formation is carried out in a diluted oxidizing gas, the similar effect is obtained by carrying out thermal oxidation while the pressure decrease degree being heightened, that is, the vacuum degree being heightened by two orders of magnitude, for example, to about 60 Pa.

Furthermore, though, in the foregoing example, the description is given while exemplifying the case of forming a plurality of types of gate insulating films with different film thicknesses in a well layer, a plurality of types of such gate insulating films can completely similarly be formed in different sites of a semiconductor chip.

As described above, the method for fabricating a semiconductor device of the present invention comprises a step of introducing an impurity capable of accelerating thermal oxidation selectively into the surface of a silicon substrate by ion implantation or the like and a step of successively carrying out oxidation and successive oxynitridation or reoxidation of the surface of the silicon substrate. Further, in the case of the foregoing ion implantation, a semiconductor chip is implanted with an ion in different doses depending on the sites and the film thickness of insulating films is changed corresponding to the dose.

In such a manner, highly reliable multigate insulating films can simply, highly precisely, and efficiently be formed in a semiconductor chip and a MOS transistor comprising a plurality of types of gate insulating films can be formed in a semiconductor chip.

Further, the value of the micro roughness as described in the conventional techniques can significantly be lowered to improve the operational characteristics of the MOS transistor. Furthermore, the dispersion of film thickness of the gate insulating films in a silicon wafer can greatly be lowered.

Like this, the fabrication yield of a semiconductor device can be improved and the fabrication cost of a semiconductor device is decreased. Further, development of a multifunctional and highly capable semiconductor device on which a memory circuit, a logic circuit, an analog circuit, and the like are mounted together can considerably be accelerated.

Although the invention has been described with reference to specific embodiments, this description is not meant to be construed in a limiting sense. Various modifications of the disclosed embodiments will become apparent to persons skilled in the art upon reference to the description of the invention. It is therefore contemplated that the appended claims will cover any modifications or embodiments as fall within the true scope of the invention.

What is claimed is:

1. A semiconductor device fabrication method comprising: an impurity introduction step of introducing an impurity capable of accelerating thermal oxidation selectively into a first region of the surface of a silicon substrate and an oxidation step of successively carrying out oxidation and oxynitridation for said first region and a second region where no impurity is introduced and forming insulating films with respectively different film thicknesses on the surface of said first region and the surface of said second region.

2. The semiconductor device fabrication method as set forth in claim 1, wherein said impurity to be introduced is one containing a halogen or rare gas atom.

3. The semiconductor device fabrication method as set forth in claim 1, wherein said impurity to be introduced contains atoms of fluorine, argon, or their mixture.

4. The semiconductor device fabrication method as set forth in claim 1, wherein introduction of said impurity is carried out by ion implantation.

5. The semiconductor device fabrication method as set forth in claim 1, wherein said fabrication method further comprises a step of introducing at maximum three regions by implanting an ion in a dose different from that in said first region.

6. The semiconductor device fabrication method as set forth in claim 1, wherein said impurity to be implanted is fluorine and the range of the dose of fluorine ion is not less than 3×10¹⁴/cm and not more than 7×10¹⁴/cm².

7. The semiconductor device fabrication method as set forth in claim 1, wherein a spontaneously oxidized film is formed on the surface of a silicon substrate before said oxidation process.

8. The semiconductor device fabrication method as set forth in claim 1, wherein said oxidation is carried out in atmosphere of an oxidizing gas diluted with nitrogen or a rare gas.

9. The semiconductor device fabrication method as set forth in claim 1, wherein reoxidation is further carried out after said oxynitridation in said oxidation process.

10. The semiconductor device fabrication method as set forth in claim 1, wherein said oxynitridation is carried out in nitrogen monoxide or in nitrous oxide.

11. The semiconductor device fabrication method as set forth in claim 1, wherein said oxidation and oxynitridation are carried out at the same temperature and in a gas atmosphere at a decreased pressure.
